(19) United States
(12) Patent Application Publication
(10) Pub. No.: US 2005/0145915 A1
(43) Pub. Date: Jul. 7, 2005

(54) Selective epi-region method for integration of vertical power MOSFET and lateral driver devices

(76) Inventors: Badredin Fatemizadeh, San Jose, CA (US); Ali Salih, Mesa, AZ (US)

Correspondence Address: QUARLES & BRADY LLP, RENAISSANCE ONE, TWO NORTH CENTRAL AVENUE, PHOENIX, AZ, 85004-2391, US

(21) Appl. No.: 10/753,030

(22) Filed: Jan. 6, 2004

(51) Int. Cl. H01L 27/108

(52) U.S. Cl. 257/302

(57) ABSTRACT

A semiconductor device has a driver device (10) in proximity to a power device (12). In making the semiconductor device, an N+ layer (24) is formed on a substrate (22). A portion of the N+ layer is removed, substantially down to the substrate, to provide a layer offset (28) between the driver device area and the power device area. An epi region of uniform thickness is formed over the driver device and power device areas. The epi region has a similar offset as the layer offset. The epi region is planarized so that the epi region over the power device area has less thickness than the epi region over the driver device area. The driver devices are formed in first and second wells (36, 38) in the thicker area of the epi region. The power device is formed in the third well (40) in the thinner area of the epi region.

### FIELD OF THE INVENTION

The present invention relates in general to semiconductor devices and, more particularly, to a selective epi-region method for integration of vertical power MOSFET and lateral driver devices.

### BACKGROUND OF THE INVENTION

Metal oxide semiconductor field effect transistors (MOSFETs) are commonly used in power transistor applications such as switching power supplies, power conversion, power management, energy systems, telecommunications, personal computer applications, motor control, automotive, and consumer electronics. Power devices generally refer to transistors and other semiconductor devices that can switch about 1.0 ampere or more of conduction current. Power MOSFETs are well known as high input impedance, voltage controlled devices which require only a relatively small charge to initiate turn-on from simple drive circuitry. The Power MOSFET ideally exhibits high drain-to-source current carrying capacity, low drain-to-source resistance (R_{DSon}) to reduce conduction losses, high switching rate with low switching losses, and high safe operating range (SOA) which provides the ability to withstand a combination of high voltage and high current.

While some power devices are discrete, it is common to integrate power devices with drivers. Accordingly, power MOSFETs, which can be either lateral or vertical devices, can be used in combination with a lateral driver circuit. The driver circuit may be as simple as a p-channel transistor and an n-channel transistor connected in a totem-pole arrangement. Other driver circuits are known to have more features. The junction between the drain of the p-channel transistor and the drain of the n-channel transistor is the output of the driver circuit, which is coupled to the gate of the power MOSFET. In one operating mode, the p-channel transistor of the driver circuit is turned on to source current directly into the gate of the power MOSFET. In another operating mode, the n-channel transistor of the driver circuit is turned on to sink current directly away from the gate of the power MOSFET. The driver circuit must supply sufficient current to charge and discharge the gate voltage of the power MOSFET. The driver circuit thus operates to turn on and off the power MOSFET in a rapid and efficient manner.

The driver circuit is typically a low voltage device, operating in the range of 5-25 volts. The power MOSFET is a higher voltage device, operating in the range of 20-30 volts. The lateral driver circuit is usually placed on the same base silicon substrate as the power device. For efficient layout considerations, the lateral driver circuit is often located in proximity to the power MOSFET.

In constructing the lateral devices, an N-epi layer is disposed above the silicon substrate. A first p-well is formed in the N-epi layer for the n-channel transistor, and an n-well is formed within the first p-well for the p-channel transistor. A second p-well is formed in the N-epi layer, in proximity to but separated from the first p-well by N-epi, for the power device. The N-epi layer under the power MOSFET is made a certain thickness, with low resistivity, to provide isolation from the high voltage components. The thickness of the N-epi layer needed to provide the necessary breakdown voltage for the power MOSFET is less than the thickness of the N-epi required for the isolation of the lateral driver devices.

Given that the lateral devices and vertical power device are located in proximity to one another and share the same N-epi layer, the N-epi under the power device has non-optimal dimensions. That is, in order to accommodate the isolation requirement for the lateral driver device and given that vertical power device has the same N-epi thickness as the lateral driver device, the N-epi under the power device ends up being thicker than is necessary to achieve the required breakdown voltage protection. The thicker N-epi under the power device increases the R_{DSon} in the conduction state of the power MOSFET, which is undesirable. The isolation requirements of the lateral driver devices has caused the R_{DSon} of the vertical power MOSFET to be less than optimized.

### SUMMARY OF THE INVENTION

In one embodiment, the present invention is a method of forming a semiconductor device comprising the steps of providing a substrate, removing a portion of the substrate to provide a layer offset in the substrate, forming an epi region of uniform thickness over the substrate, wherein the epi region has a similar offset as the layer offset, and planarizing the epi region so that the epi region over a first portion of the substrate has less thickness than the epi region over a second portion of the substrate.

In another embodiment, the present invention is a method of forming an integrated circuit having a driver device in proximity to a power device comprising the steps of forming a substrate having a driver device area and a power device area, forming a layer offset between the driver device area and the power device area, forming an epi region over the driver device area and the power device area, and planarizing the epi region so that the epi region over the power device area has less thickness than the epi region over the driver device area.

In yet another embodiment, the present invention is a method of forming a first semiconductor device in proximity to a second semiconductor device on an integrated circuit comprising the steps of forming a first layer of semiconductor material with a layer offset between a first semiconductor device area and a second semiconductor device area, forming an epi region over the first semiconductor device area and the second semiconductor device area, and planarizing the epi region such that the epi region over the second semiconductor device area has less thickness than the epi region over the first semiconductor device area.

### BRIEF DESCRIPTION OF THE DRAWINGS

FIG. 1 is a schematic diagram of a driver circuit and power MOSFET; and

FIGS. 2-5 illustrate cross-sectional views of the driver circuit and power MOSFET devices.

### DETAILED DESCRIPTION OF THE DRAWINGS

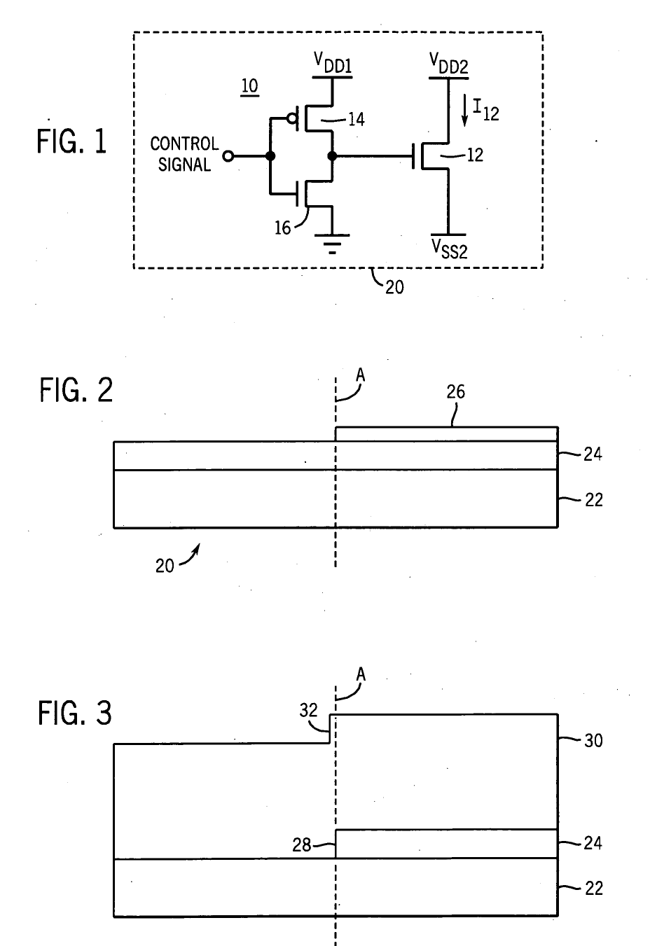

Referring to FIG. 1, driver circuit 10 is shown with an output coupled to the gate of power MOSFET 12. Driver circuit 10 and power MOSFET 12 are formed in proximity to one another on a single silicon substrate and packaged as an integrated circuit (IC) 20. IC 20 may contain other signal processing circuitry. The IC containing power MOSFET 12 is commonly used in power transistor applications such as switching power supplies, power conversion, power management, energy systems, telecommunications, personal computer applications, motor control, automotive, and consumer electronics.

Driver circuit 10 must supply sufficient current to charge and discharge the gate voltage of power MOSFET 12. Power MOSFET 12 is capable of switching more than 1.0 ampere of conduction current I₁₂. Power MOSFET 12 exhibits high drain-to-source current carrying capacity, low drain-to-source resistance (R_{DSon}) to reduce conduction losses, high switching rate with low switching losses, and high safe operating range (SOA) which provides the ability to withstand a combination of high voltage and high current.

Driver circuit 10 includes p-channel transistor 14 and n-channel transistor 16. A control signal is applied to the common gates of transistors 14 and 16. If the control signal is low, then transistor 14 conducts and transistor 16 is turned off. Transistor 14 sources current to the gate of power MOSFET 12 to turn on the power device in a rapid manner. If the control signal is high, then transistor 14 turns off and transistor 16 conducts. Transistor 16 sinks current away from the gate of power MOSFET 12 to turn off the power device in a rapid manner.

Driver circuit 10 operates with a low supply voltage V_{DD1} on the order of 5-25 volts and ground potential. Power MOSFET 12 operates with a higher supply voltage V_{DD2} in the range of 20-30 volts or more, and supply voltage V_{SS2}. As noted above, driver circuit 10 and power MOSFET 12 are formed in proximity to one another on the same silicon substrate within IC 20. The lateral devices of driver circuit 10 will require isolation for protection from the higher voltage of power MOSFET 12. At the same time, it is desirable to keep the R_{DSon} of power MOSFET 12 to a low value.

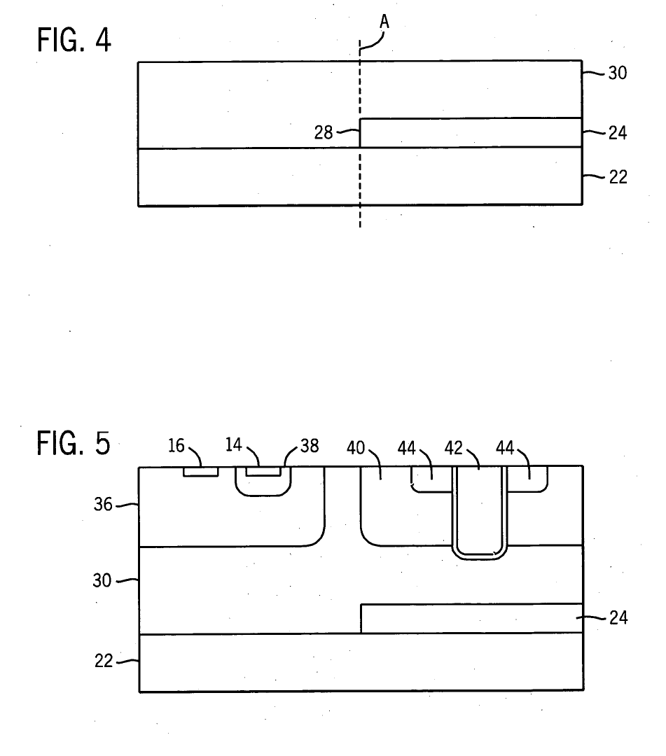

Turning to FIG. 2, a cross-sectional view of IC 20 is shown. Line A marks the boundary between the lateral driver device area, i.e., where driver circuit 10 is to be formed, and the vertical power device area, i.e., where power MOSFET 12 is to be formed. IC 20 includes silicon substrate 22 having an N+ doping concentration. Substrate 22 is doped with N-type semiconductor material such as phosphorus or arsenic at a concentration level of 1*E20 atoms/centimeter (cm)³. Substrate 22 is about 200-250 microns in thickness. Substrate 22 provides structural support for IC 20 and forms the drain of the vertical power MOSFET 12. N+ layer 24 is disposed over substrate 22. N+ layer 24 has a thickness of about 2 microns and is doped with N-type semiconductor material on the order of 1*E19 phosphorus or arsenic atoms/cm³.

In one aspect, N+ layer 24 can be a separate semiconductor layer with respect to substrate 22. In another aspect, N+ layer 24 functions as an extension of, and can be considered an integral part of, substrate 22. In another embodiment, the area defined by substrate 22 and N+ layer 24 can be a single uniform-concentration substrate region. In another view, N+ layer 24 can be omitted altogether.

Mask layer 26 is disposed over a portion of N+ layer 24 corresponding to the vertical power device area, i.e., that area to the right of line A. The portion of N+ layer 24 corresponding to the lateral driver device area, i.e., that area to the left of line A, is unprotected in the subsequent etching process. With mask layer 26 in place, the portion of N+ layer 24 which is under the lateral driver device area is etched away, substantially down to substrate 22. Mask layer 26 is then removed as shown in FIG. 3. After the etching process, there is a 2-micron offset or stair-step 28 between substrate 22 and N+ layer 24 at the boundary between the lateral driver device area and the vertical power MOSFET area.

The portion of N+ layer 24 that has been etched away constitutes the removed portion of N+ layer 24. The portion of N+ layer 24 that had been under mask layer 26 constitutes the remaining portion of N+ layer 24. The etching process may be stopped before reaching substrate 22, may be stopped at substrate 22, or may continue into substrate 22. The height of offset 28 is thus determined by the original thickness of N+ layer 24, and the degree or amount of etching that takes place, all of which can be controlled by the design and manufacturing process.

An epi region 30 is grown or formed to a relatively uniform thickness of about 6 microns across substrate 22 and N+ layer 24. Epi region 30 receives an N− doping concentration of phosphorus or arsenic on the order of 5*E15 to 5*E16 atoms/cm³. The thickness of epi region 30 above substrate 22 to the left of line A is the same as the thickness of epi region 30 above N+ layer 24 to the right of line A. Accordingly, in the process of forming N-epi region 30, the offset or stair-step 28 between substrate 22 and N+ layer 24 causes a similar offset or stair-step 32 to N-epi region 30, as shown. The offset 32 may be a step function, gradual, angled, or inclined, with a linear or non-linear slope. N-epi region 30 is a single, continuous region.

N-epi region 30 is planarized in FIG. 4 with etch-back and polish steps to create a flat or even surface across the lateral driver device area and the vertical power device area, i.e., on both sides of line A. The planarization can take N-epi region 30 to any thickness. In one embodiment, the step of planarizing N-epi region 30 leaves the N-epi to the right of line A about 4 microns in thickness, while the N-epi to the left of line A remains 6 microns.

In FIG. 5, p-well 36 is implanted in N-epi region 30 in the lateral driver device area for driver circuit 10. N-channel transistor 16 is formed in p-well 36. An N-well 38 is implanted in p-well 36 for p-channel transistor 14. P-well 36 has a doping concentration on the order of 1*E16 to 5*E17 boron atoms/cm³. A p-well 40 is implanted in N-epi region 30 in the vertical power device area for power MOSFET 12. P-well 40 has a doping concentration on the order of 1*E17 to 5*E17 boron atoms/cm³. To build a vertical device, a trench 42 is formed for the gate of power MOSFET 12 and source regions 44 are formed on both sides of trench 42. Substrate 22 is the drain of power MOSFET 12. When driver circuit 10 charges the gate of power MOSFET 12, a conduction path for current I₁₂ is created from source regions 44, vertically along trench 42, to the drain in substrate 22. Although power MOSFET 12 is shown as a vertical device, the power MOSFET can be formed as a lateral device.

It can be seen in FIG. 5 that the N-epi region under p-well 36 is thicker than the N-epi region under p-well 40. The difference in thickness across N-epi region 30 is based on or arises from the formation of offset 28 from the manufacturing steps described herein. The N-epi region under p-well 36 is about 4-8 microns in thickness, depending on the height of offset 28 and the amount or degree of planarization described above, which has been selected to provide the proper isolation for driver circuit 10 from the high voltage effects of power MOSFET 12. The N-epi region under p-well 40 is about 4-6 microns in thickness, again depending on the height of offset 28 and the amount or degree of planarization, which has been selected to provide the proper breakdown voltage for power MOSFET 12. In other terms, the aspect ratio of the N-epi region under p-well 36 to the N-epi region under p-well 40 is between about 1.5:1 to 2.0:1.

The difference in thickness of the N-epi region under p-well 36 and the N-epi region under p-well 40, which is readily controllable by selecting the desired height of offset 28, allows design considerations for the lateral driver devices and vertical power devices to be independently optimized. Driver circuit 10 has the necessary isolation, while power MOSFET 12 does not suffer from the N-epi overhead as found in the prior art. Power MOSFET 12 has a lower R_{DSon} with the thinner N-epi region under p-well 40.

By creating a vertical or inclined offset or stair-step between substrate 22 and N+ layer 24, forming a uniform thickness of N-epi over both substrate 22 and N+ layer 24, and then planarizing the N-epi region to create an even surface, the desired thicker N-epi region 30 under p-well 36 and the desired thinner N-epi region 30 under p-well 40 are formed to optimize both the design considerations for driver circuit 10 and for power MOSFET 12. N-epi region 30 is grown, as shown in FIG. 4, to the proper thickness, 6 microns in the present discussion, to provide the necessary isolation for driver circuit 10. The thickness of N+ layer 24 and the depth of the etching process is selected by the amount that N-epi region 30, as grown, should be reduced, i.e., 2 microns, in order to provide a thinner N-epi region under p-well 40, i.e., 4 microns, that will give the needed breakdown voltage for power MOSFET 12 while still maintaining a low R_{DSon}. The offset 32 in the N-epi above the vertical power MOSFET area, corresponding to offset 28, which in turn is determined by the thickness of N+ layer 24 and the depth of the etching process, is removed in the planarization step to provide the thinner N-epi under power MOSFET 12. The height of the offset 28 between substrate 22 and N+ layer 24 controls the differential in epi thickness between the later driver device area and the vertical power device area. The selected formation of the N-epi region has provided for the integration of the lateral driver devices and the vertical power device on the same substrate while enhancing design considerations for both. The lateral driver device has a thicker N-epi to provide proper isolation, while the vertical power device has a thinner N-epi to provide the needed breakdown voltage for power MOSFET 12 and yet still maintain low R_{DSon}.

The present description has given specific dimensions for the different thickness of N-epi region 30. Other dimensions of N-epi region 30, under the lateral driver device area and the vertical power device area, are within the scope of the present invention.

A person skilled in the art will recognize that changes can be made in form and detail, and equivalents may be substituted for elements of the invention without departing from the scope and spirit of the invention. The present description is therefore considered in all respects to be illustrative and not restrictive, the scope of the invention being determined by the following claims and their equivalents as supported by the above disclosure and drawings.

1. A method of forming a semiconductor device, comprising:
providing a substrate;
removing a portion of the substrate to provide a layer offset in the substrate;
forming an epi region of uniform thickness over the substrate, wherein the epi region has a similar offset as the layer offset; and
planarizing the epi region so that the epi region over a first portion of the substrate has less thickness than the epi region over a second portion of the substrate.

2. The method of claim 1, wherein the substrate is N-type semiconductor material.

3. The method of claim 1, further include the steps of:
disposing a first layer of semiconductor material over the substrate; and
removing a portion of the first layer to provide the layer offset.

4. The method of claim 3, wherein the step of removing a portion of the first layer includes the step of removing the first layer substantially down to the substrate.

5. The method of claim 1, further including the step of forming a first well in a thicker area of the epi region.

6. The method of claim 5, further including the steps of:
forming a second well in the first well;
forming a first transistor in the first well; and
forming a second transistor in the second well.

7. The method of claim 5, further including the step of forming a second well in a thinner area of the epi region.

8. The method of claim 7, further including the step of forming a power transistor in the second well.

9. A method of forming an integrated circuit having a driver device in proximity to a power device, comprising:
forming a substrate having a driver device area and a power device area;
forming a layer offset between the driver device area and the power device area;
forming an epi region over the driver device area and the power device area; and
planarizing the epi region so that the epi region over the power device area has less thickness than the epi region over the driver device area.

10. The method of claim 9, wherein the substrate is N-type semiconductor material.

11. The method of claim 9, further including the step of forming a first layer of semiconductor material over the substrate.

12. The method of claim 11, further including the step of removing a portion of the first layer substantially down to the substrate.

13. The method of claim 9, wherein the step of forming a layer offset further includes the steps of:
masking a first portion of the substrate in the power device area; and
etching a second portion of the substrate in the driver device area.

14. The method of claim 9, further including the steps of:
forming a first well in the driver device area of the epi region;
forming a second well in the first well;
forming a first transistor in the first well;
forming a second transistor in the second well;
forming a third well in the power device area of the epi region; and
forming a power transistor in the third well.

15. A semiconductor device made by the process comprising the steps of:
providing a substrate;
forming a layer offset in the substrate;
forming an epi region over the substrate; and
planarizing the epi region so that the epi region over a first portion of the substrate has less thickness than the epi region over a second portion of the substrate.

16. The semiconductor device of claim 15, further including the steps of:
disposing a first layer of semiconductor material over the substrate; and
removing a portion of the first layer substantially down to the substrate to provide the layer offset.

17. The method of claim 15, wherein the step of forming a layer offset further includes the steps of:
masking the first portion of the substrate; and
etching the second portion of the substrate.

18. The semiconductor device of claim 15, further including the steps of:
forming a first well in the thicker area of the epi region;
forming a second well in the first well;
forming a first transistor in the first well;
forming a second transistor in the second well;
forming a third well in the thinner area of the epi region; and
forming a power transistor in the third well.

19. A method of forming a first semiconductor device in proximity to a second semiconductor device on an integrated circuit, comprising:
forming a first layer of semiconductor material with a layer offset between a first semiconductor device area and a second semiconductor device area;
forming an epi region over the first semiconductor device area and the second semiconductor device area; and
planarizing the epi region such that the epi region over the second semiconductor device area has less thickness than the epi region over the first semiconductor device area.

20. The method of claim 19, further including the steps of:
forming a first well in the first semiconductor device area of the epi region;
forming a second well in the first well;
forming a first transistor in the first well; and
forming a second transistor in the second well.

21. The method of claim 19, further including the steps of:
forming a first well in the second semiconductor device area of the epi region; and
forming a power transistor in the first well.

22. A semiconductor device, comprising:
a substrate having an offset between first and second portions of the substrate; and
an epi region disposed over the first and second portions of the substrate, the epi region having a first thickness above the first portion and a second thickness above the second portion which is less than the first thickness above the first portion of substrate.

23. The semiconductor device of claim 22, further including:
a first well disposed in the epi region above the first portion of the substrate;
a second well disposed in the first well;
a first transistor formed in the first well; and
a second transistor formed in the second well.

24. The semiconductor device of claim 22, further including:
a first well disposed in the epi region above the second portion of the substrate; and
a power transistor formed in the first well.
